(19) United States
(12) Patent Application Publication
(10) Pub. No.: US 2016/0326932 A1
(43) Pub. Date: Nov. 10, 2016

(54) THERMOELECTRIC GENERATOR UNIT AND EXHAUST SYSTEM

(71) Applicant: Faurecia Emissions Control Technologies, Germany GmbH, Augsburg (DE)

(72) Inventors: Maria Karl, Augsburg (DE); Sylvain Pellissard, Champrougier (FR); Martin Kluge, Koenigsbrunn (DE)

(21) Appl. No.: 15/146,945

(22) Filed: May 5, 2016

(30) Foreign Application Priority Data
May 7, 2015 (DE) 10 2015 107 164.9

(51) Int. Cl. F01N 5/02; H01L 35/30; H01L 35/02

(52) U.S. Cl. CPC F01N 5/025; H01L 35/02; H01L 35/30

(57) ABSTRACT

A thermoelectric generator unit, in particular for an exhaust system of a combustion engine, has an outer housing in which at least one first inner duct is arranged and through which a hot fluid flows. The unit has at least one thermoelectric module which is in thermal contact with the first inner duct on a hot side. At least one elastic compensating element is arranged within the outer housing, which generates a clamping force acting on the thermoelectric module. At least 60% of the elastic compensating element is made of an organic material.

### RELATED APPLICATION

This application claims priority to German application 10 2015 107 164.9, filed May 7, 2015.

### FIELD OF THE INVENTION

The invention relates to a thermoelectric generator unit, in particular for coupling to an exhaust gas pipe of a combustion engine, and to an exhaust system.

### BACKGROUND

In a thermoelectric generator, thermal energy is converted into electric energy according to the Seebeck effect. To this end, several so-called thermoelectric modules are usually fitted in the thermoelectric generator, a number of series-connected thermoelectric elements made of specific material pairs of different metals or semi-conductor materials being arranged in each module. A temperature gradient is applied via these thermoelectric elements, as a result of which the thermoelectric module generates an electric voltage.

Thermoelectric modules of this type are on the market in the form of planar, thin, encapsulated individual units.

The thermal energy of an exhaust-gas flow of an exhaust system of a vehicle is often used to generate the temperature gradient. The possibility of recuperating energy from the heat of the exhaust gas gains an increasing attractiveness as fuel prices increase. The yield of electric energy is the highest, the better the thermoelectric modules can be brought in direct contact with the heat of the exhaust gas. The components are therefore often held together in thermoelectric generator units by clamping forces to bring the hot and cold sides of the thermoelectric modules in direct thermal contact with the respective components, which provide the temperature difference without disturbing adhesive layers. To this end, it is for example known to use mats of wire meshes or bearing mats for substrates of catalysts and particulate filters which include mineral fibers.

The object of the invention is to obtain a high ecological quality of a thermoelectric generator unit and of an exhaust system.

### SUMMARY

The present invention provides a thermoelectric generator unit, in particular for an exhaust system of a combustion engine, having an outer housing in which at least one first inner duct is arranged through which a hot fluid flows. At least one thermoelectric module is in thermal contact with the first inner duct on a hot side, and at least one elastic compensating element is arranged within the outer housing, and is configured to generate a clamping force acting on the thermoelectric module. At least 60% of the elastic compensating element is made of an organic material. It surprisingly became apparent that both a durable pressure force and a sufficient thermal and acoustic insulation to the outside can be obtained with organic materials at low material costs and with a simple processability.

In a first embodiment, the organic material comprises an organic natural material or is an organic natural material. Organic materials in particular means here renewable raw materials of an animal or plant origin.

It is possible that the major part of the elastic compensating element or that even the complete elastic compensating element is made of the organic natural material.

Organic natural materials that can be used include, for example, cork, flax, hemp, grass, bamboo fibers, bast, jute, sisal, kenaf, abacá fibers, coconut fibers, wool, in particular sheep's wool, seagrass, wood fibers, cotton or kapok. It is of course also possible to use a mixture of these fabrics or of other materials with these fabrics.

The organic natural material can, for example, be a fiber material. Fiber materials generally have the advantage of being easy to process and having good permanently elastic properties.

As to the non-fibrous organic natural materials, in particular cork is advantageous due to its high elasticity, its good acoustic and thermal insulating ability, and its high temperature resistance.

To increase the temperature resistance, the organic natural material, if necessary, may be treated with a substance which increases the thermal stability thereof. Substances could be used here which are also used for treating organic natural materials as insulating material, for example, in house building, for example known flame retardants which inhibit the admission of oxygen.

In a second embodiment, the organic material comprises a polymer, both suitable biopolymers and suitable synthetic polymers being adapted to be used. Advantageous polymers are in particular elastomers, polyurethanes, or high-temperature silicones, it is however also possible to use any other suitable polymer. According to a variant of the invention, any material can be considered as “organic material” which contains carbon atoms, i.e. also the so-called inorganic polymers such as silicones in which no carbon atoms are contained in the polymer backbone, but other elements such as silicon.

The advantage of organic materials is also the fact that they are in principle substantially electrically insulating.

At least 80%, in particular at least 90%, of the elastic compensating element and optionally the entire compensating element are preferably made of an organic material.

The organic material can be a single fabric but also a mixture, for example, of different organic natural materials, different polymers or also a mixture of organic natural materials with one or more polymers.

The organic material should however have a temperature resistance up to at least 180° C. and preferably resist such temperatures over several hours.

In addition to the organic material, the elastic compensating element can comprise a suitable functional material on an inorganic basis, for example a filling material such as fibers or air.

In a possible variant, the elastic compensating element is provided in the form of a mat. The mat may have a uniform thickness before the fitting in the thermoelectric generator unit such that it can be produced as surface material and merely has to be cut to the required dimensions.

It is however also possible that the elastic compensating element has a component-adapted shape having a varying thickness, the compensating element obtaining this shape before the mounting thereof into the thermoelectric generator unit. The shaping can, for example, be realized by a three-dimensional cutting of a block material, but also by conventional known injection-molding, casting, pressing, or foaming processes in appropriate tool molds.

In this way, it is also possible to easily manufacture elastic compensating elements with complex outer geometries such that a very homogeneous pressure force on the thermoelectric modules is achieved at low costs and the energy yield and the useful life of the thermoelectric generator unit can thus be increased.

Suitable materials for this manufacturing type are, for example, cork or elastomers. Rigid three-dimensional bodies having a variable thickness and component-adapted contours can easily be pre-fabricated from these materials.

The elastic compensating element can be configured in one piece, it can however also be composed of several single parts, which facilitates the manufacture of elastic compensating elements with complex shapes.

The elastic compensating element can also comprise a cured foam which fills a space area within the outer housing.

In a possible variant, the thermoelectric compensating element is prefabricated in a foaming mold before mounting in the thermoelectric generator unit, and is installed when entirely cured. The assembly of the elastic compensating element of several single parts is also possible here.

In a further variant, the organic material of the elastic compensating element is introduced into the outer housing in a fluid form, optionally as a foam, and fills the available space there and is cured in this shape. A very homogeneous pressure force and a good attachment of the thermoelectric modules in the outer housing are thus obtained in a durable manner.

The elastic compensating element can, for example, be arranged on the inside of the outer housing where it produces a clamping force between the outer housing and the components of the thermoelectric generator unit that are arranged within the outer housing. In this position, the elastic compensating element simultaneously generates a thermal and acoustic insulation with respect to the environment of the exhaust system. The lowest temperature load furthermore occurs at this point such that the temperatures are normally below the limit temperatures of the organic natural materials.

The outer housing may have structures, in particular ribs, projections, or recesses. The elastic compensating element preferably rests in a planar manner on the inside of the outer housing in the region of the structures.

This can be obtained by an elastic compensating element having a uniform initial thickness by compressing the elastic compensating element more strongly in sections upon mounting to be adapted to follow the structures. The required flexibility and elasticity can be simply achieved for the elastic compensating element by using organic natural materials but also elastomers, for example, in order to obtain a sufficient adaptability to the structures of the outer housing in a durable manner and by preserving the elastic properties.

Alternatively, the elastic compensating element can however also be prefabricated in a complex three-dimensional shape as described above, which represents the geometry of the inside of the outer housing in a section of its surface. In this case, the compression force onto the elastic compensating element by the outer housing is substantially identical at each point of the contact surface to the inside of the outer housing such that a very homogeneous pressure force is transmitted to the thermoelectric modules via the surface of the elastic compensating element.

In one embodiment, the unit includes at least a second inner duct through which a cold fluid flows, and which is thermal contact with a cold side of the thermoelectric module, within the outer housing to increase the temperature gradient. The second inner duct can be in fluid communication with a cooling circuit which is, for example, part of a general cooling circuit of the vehicle. The temperature gradient and thus the yield of electric energy can in this way be maximized.

Each of the inner ducts is preferably made of its own tube, for example of a metallic tube such that the ducts of the thermoelectric generator unit can be manufactured at low costs. It would alternatively also be possible to realize the ducts in specifically shaped elements, such as of a sintered ceramic material.

The thermal contact with the inner duct can be realized in that the thermoelectric module directly contacts the duct wall of the respective inner channel. It is also possible that the duct wall has an opening in the region of the thermoelectric module and that the thermoelectric module projects into the channel such that the hot or cold side thereof is in direct contact with the fluid flowing through the inner duct.

Alternatively, or in addition to the placement of the elastic compensating element on the inside of the outer housing, an elastic compensating element can also be arranged between two inner ducts. The elastic compensating element is preferably in direct contact with the walls of each of the two adjacent inner ducts. It is here advantageous if a cold fluid flows through the two inner ducts to keep the temperature load for the organic natural material as low as possible.

The invention furthermore relates to an exhaust system, in particular of a vehicle, comprising a thermoelectric generator unit according to the invention. The outer housing has an exhaust gas inlet and an exhaust gas outlet extending to or from the inner duct.

### BRIEF DESCRIPTION OF THE DRAWINGS

FIG. 1 a schematic cross-sectional view of a thermoelectric generator unit according to the invention as a part of an exhaust system according to the invention in accordance with a first embodiment,

FIG. 2 a schematic view in a longitudinal section of a thermoelectric generator unit according to the invention as a part of an exhaust system according to the invention in accordance with a second embodiment,

FIG. 3 a schematic view in a longitudinal section of a thermoelectric generator unit according to the invention as a part of an exhaust system according to the invention in accordance with a third embodiment,

FIG. 4 a schematic, perspective cross-sectional view of a thermoelectric generator unit according to the invention as a part of an exhaust system according to the invention in accordance with a fourth embodiment, and

FIG. 5 a schematic cross-sectional view of a thermoelectric generator unit according to the invention as a part of an exhaust system according to the invention in accordance with a fifth embodiment.

### DETAILED DESCRIPTION

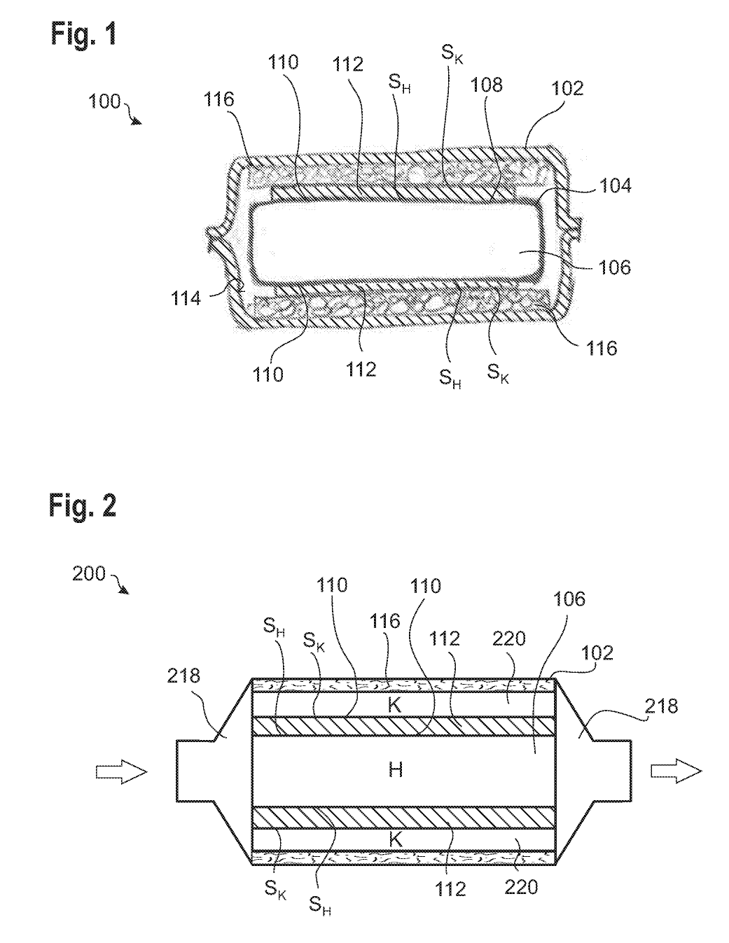

FIG. 1 shows a cross-section through a thermoelectric generator unit 100 according to a first embodiment which is part of a vehicle exhaust system.

A tube 104 is received in a metallic outer housing 102 which is here composed of two half shells. The tube 104 is connected to an exhaust-gas pipe (not shown) in the exhaust system of a combustion engine such that the exhaust gas that forms a hot fluid H flows through a first inner duct 106 formed within the tube 104. The wall of the tube 104 simultaneously forms a duct wall 108 which delimits the inner duct 106.

Here, the tube 104 is configured to be flattened on two opposite sides such that one respective planar resting surface 110 is provided outside on the duct wall 108. Several respective planar and known thermoelectric modules 112 are arranged along these planar resting surfaces 110 on both sides of the tube 104, which directly rest on the outside of the tube 104, thus directly on the duct wall 108 via their hot side S_{H} in the present example.

In an alternative embodiment which is not shown, the duct wall 108 includes openings through which the hot sides S_{H} of the thermoelectric modules 112 project such that these hot sides S_{H} are in direct contact with the hot exhaust-gas flow within the first inner duct 106.

In a known manner, a number of individual thermoelectric elements of different suitable material pairs are arranged in each of the thermoelectric modules 112. The respective thermoelectric module 112 is encapsulated with respect to the environment by a housing. Each thermoelectric module 112 can thus be installed as a separate constructional unit in the thermoelectric generator unit 100.

The individual thermoelectric modules 112 are electrically connected to each other, and the electric voltage generated therein can be tapped via known connection pipes that are not shown.

The entire planar surface 110 is preferably substantially entirely covered by thermoelectric modules 112 on both sides of the tube 104 to maximize the yield of electric energy.

On the cold side S_{K} of the thermoelectric modules 112 opposite the hot side S_{H}, an elastic compensating element 116 is arranged between the thermoelectric module 112 and the inside 114 of the outer housing 102.

At least 60%, and for example at least 80%, or at least 90% of the elastic compensating element 116 or the entire elastic compensating element 116 are made of an organic material. In a first variant, the organic material is an organic natural material, here a material on an animal or plant basis. In a second variant, the organic material is a polymer containing carbon atoms.

For all embodiments, in particular, cork can be taken into consideration as an organic natural material. However, other materials such as fiber materials may also be used. The following materials have to be mentioned here: flax, hemp, grass, bamboo fibers, bast, jute, sisal, kenaf, abacá fibers, coconut fibers, animal wool, seagrass, wood fibers, cotton or kapok. A mixture of these fabrics or a mixture of other materials with these fabrics may also be used. If possible, the organic natural materials are treated with a substance which increases the thermal stability thereof, for example with a flame resistant material.

High-temperature silicones or elastomers are, for example, used as a polymer. Polymers can also be employed in a foam form. Polyurethanes and suitable thermoplastic polymers are, for example, appropriate here.

Organic natural materials and polymers can also be used in a mixture.

It became apparent that compensating elements 116 having a high proportion of organic materials can resist a temperature of up to 180° C. without difficulty for a longer period without losing its structural or elastic properties.

It is however generally recommended to arrange the elastic compensating element 116 at the positions within the outer housing 102 where the lowest temperature load is prevailing.

A possible position of this type is the arrangement shown in FIG. 1 directly on the inside 114 of the outer housing 102.

The elastic compensating element 116 has a certain inherent elasticity and is installed within the outer housing 102 in a compressed state to thus exert a clamping force onto the thermoelectric modules 112 and the tube 104 that is so high that the latter are retained non-movable within the outer housing 102. The individual components, in particular the tube 104 can also be fastened at certain points to the outer housing 102. However, depending on the configuration of the elastic compensating element 116, an additional fastening can however also be dispensed with.

In the configuration shown in FIG. 1, two elastic compensating elements are provided which are respectively arranged above and below the tube 104 on the inside 114 of the outer housing 102 in this figure. It would of course also be possible to use only one elastic compensating element 116 and to wrap the assembly of the tube 104 and the thermoelectric modules 112 arranged thereon with the elastic compensating element 116.

Here, the elastic compensating element 116 has the form of a thin, flexible mat and is thus a flat object which has a considerably larger extension in its longitudinal and transversal direction than its thickness.

In the manufacture of the thermoelectric generator unit 100, the elastic compensating element 116 is cut from a strip with a uniform thickness in a first variant, and this blank is arranged between the inside 114 of the outer housing 102 and the cold side S_{K} of the thermoelectric modules 112. The elastic compensating element 116 can then be deformed to compensate possibly provided structures on the inside 114 of the outer housing 102 (cf. also FIG. 4) or on the cold side S_{K} of the thermoelectric modules 112 and to follow the latter. During mounting, the elastic compensating element 116 is compressed to a certain degree such that due to the elastic properties of the elastic compensating element 116, a prestress is build up which exerts a permanent clamping force onto the assembly made of the thermoelectric modules 112 and the tube 104.

In a second variant, the elastic compensating element 116 is prefabricated in a complex, three-dimensional shape with varying dimensions along its extension, and is inserted into the outer housing 102. The outside of the elastic compensating element 116 oriented to the inside 114 of the outer housing 102 reproduces the geometry of the inside 114 such that a continuous resting surface is produced between the inside 114 of the outer housing 102 and the outside of the elastic compensating element 116.

In contrast thereto, the side oriented towards the thermoelectric modules 112 or towards the inner ducts 106 in the following embodiments is preferably configured in a planar manner to rest in a flat manner on the outsides of the thermoelectric modules 112 or of the inner ducts 106 which are also planar.

The compression force acting onto the elastic compensating element 116 is in this case very homogeneous and varies only little over the elastic compensating element 116.

This variant is in particular applicable if the outer housing 102 is provided with structures as is, for example, the case in the embodiment shown in FIG. 4.

In a third variant, the elastic compensating element 116 is produced by curing a polymer foam within the outer housing 102.

In this case, a fluid foam material of a polymer, for example of polyurethane, is introduced into a predetermined region of the outer housing 102 where the foam is cured to form the elastic compensating element 116. It is possible that the volume of the foam is again increased in the course of this foaming.

In the description of the following embodiments, and for clarity reasons, the already known reference numbers are respectively kept for the already introduced components which are present in the same or in a slightly modified form in the other embodiments.

FIG. 2 shows a second embodiment of a thermoelectric generator unit 200. The latter is shown in a longitudinal section such that connecting pipes 218 at both longitudinal ends for the connection with the exhaust-gas pipe are also visible here. Such connecting pipes are also provided in the thermoelectric generator units of the other embodiments. The left-hand connecting pipe 218 defines an inlet and the right-hand one an outlet for exhaust gas. All outer housings 102 shown in the figures include an inlet and an outlet for exhaust-gas leading to or away from the at least one inner duct 106.

Unlike the first embodiment, a second inner duct 220 is respectively arranged on the cold sides S_{K} of the thermoelectric modules 112, a cold fluid K flowing therethrough which is for example provided by a cooling circuit of the combustion engine or an air-conditioning unit of the vehicle. The second inner ducts 220 are here respectively formed by a separate tube like the first inner duct 106.

In the present example, the elastic compensating element 116 is completely wrapped around the assembly composed of the tubes forming the inner ducts 106, 220 and of the thermoelectric modules 112 arranged therebetween and is clamped between the outsides of the tubes forming the second inner ducts 220 and the inside of the outer housing 102, as described in the first embodiment.

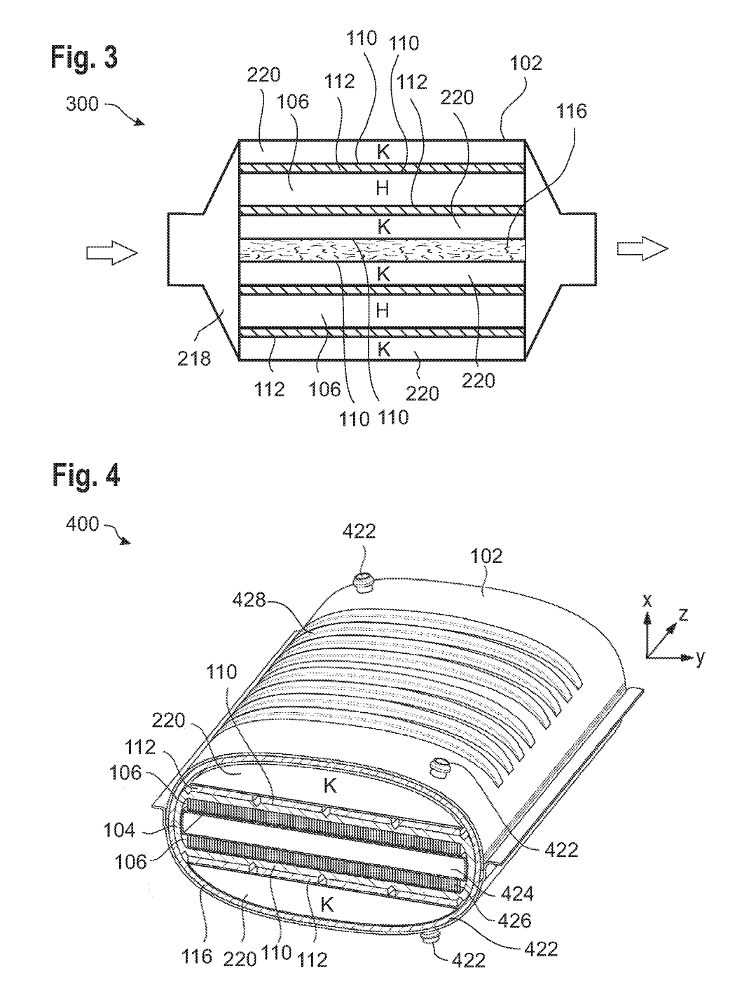

FIG. 3 shows a third embodiment of a thermoelectric generator unit 300.

In this example, the elastic compensating element 116 is not arranged on the inside of the outer housing 102 but is placed in the middle of the outer housing 102 between two second inner ducts 220 which carry cold fluid K. The temperature load for the elastic compensating element 116 is also comparatively low at this point within the thermoelectric generator unit 300. The walls of all inner ducts 106, 220 are also flattened on the side facing the elastic compensating element 116, and these flat sides 110 are oriented parallel to each other.

The elastic compensating element 116 can be a flat mat also in the present example, which approximately has the dimension of the flat side 110 of the second inner duct 220.

In this example, it is however also possible to manufacture the elastic compensating element 116 by introducing a foamed organic material, for example a polyurethane foam, which is cured within the outer housing 102 and has the required elasticity to exert a permanent pressure force onto the components of the thermoelectric generator 300.

A total of four groups of thermoelectric modules 112 is provided here, which are arranged on two first inner ducts 106 which carry hot fluid H. The thermoelectric modules 112 are respectively positioned between a first and a second inner duct 106, 220 so that the hot side S_{H} is respectively in contact with the wall of the first inner duct 106 and the cold side S_{K} is respectively in contact with the wall of the second inner duct 220. Here, the inner ducts 106, 220 could of course also be configured such that the thermoelectric modules 112 project therein and are in direct contact with the hot or cold fluid H, K.

The clamping force holding the assembly composed of the tubes forming the inner ducts 106, 220 and of the thermoelectric modules 112 clamped in the outer housing 102 may entirely be applied, for example, by an outer housing 102 manufactured with an undersize and an elastic compensating element 116 compressed thereby. At least one elastic compensating element 116 could additionally be provided on the inside of the outer housing 102, for example.

In this example, the assembly of FIG. 3 is formed above the elastic compensating element 116 in a mirror-inverted manner to the assembly below. Further configurations are of course also conceivable.

FIG. 4 shows a fourth embodiment of a thermoelectric generator unit 400. The construction is similar to the embodiment of FIG. 2, an elastic compensating element 116 extending entirely along the inside of the outer housing 102 and enclosing an assembly composed of a tube 104 and of two tubes respectively forming a second inner duct 220. Two groups of thermoelectric modules 112 are respectively arranged on the flat side of the tube 104 and are in contact with the wall of the tube 104 via their hot sides and are in contact with the wall of the second inner ducts 220, through which cooling liquid flows, via their cold sides S_{K}.

FIG. 4 also shows a possibility to configure terminals 422 for the admission and the discharge of the cold fluid K for the second inner ducts 220 in the outer housing 102.

As a characteristic feature, the tube 104 is here subdivided so that a bypass duct 424 is formed which is arranged between two first inner ducts 106. The wall 108 of the tube 104 encloses both first inner ducts 106 and a bypass duct 424. For example, in case the temperature load for the thermoelectric modules 112 becomes too high during operation of the combustion engine, the exhaust-gas flow can then be switched in a manner that is not shown such that at least most part of the exhaust gas flows through the bypass duct 424 and the thermoelectric modules 112 are thus thermally relieved.

For a better thermal absorption, ribs 426 are, in this example, formed in the first inner ducts 106 which absorb the heat of the exhaust gas and transmit it to the wall 108 of the tube 104 and thus to the hot side S_{H} of the thermoelectric modules 112.

In this embodiment, the outer housing 102 has an oval cross-section.

In this example, the outer housing 102 further includes several stabilizing structures 428 in the form of transverse ribs. Due to its inherent elasticity, the elastic compensating element 116 adjusts to these structures 428. In this case, it is thus also possible to use an initially flat elastic compensating element 116 having a uniform thickness before mounting.

In a variant that is not shown, the elastic compensating element 116 is prefabricated as a three-dimensional molded part the side of which that faces the inside 114 of the outer housing 102 follows the course of the structures 428.

Cork, for example, is appropriate as an organic material, the cork being adapted to be brought to the desired shape in a pressing method. The use of an elastomer which is, for example, adapted to be injection-molded, or the use of a rigid foam curing before mounting in a foam mold is conceivable.

In the embodiment shown in FIG. 4, the second inner ducts 220 are configured in a flat manner only on the side oriented to the thermoelectric modules 112, but on the side facing the outer housing 102, they follow the oval cross-section of the housing. It would also be possible to realize the second inner ducts 220 with a rectangular cross-section and instead of this to configure the elastic compensating element 116 with a semi-oval cross-section such that it has a flat side which is then turned towards the outside of the second inner ducts 220, and a curved side following the course of the inside 114 of the outer housing 102.

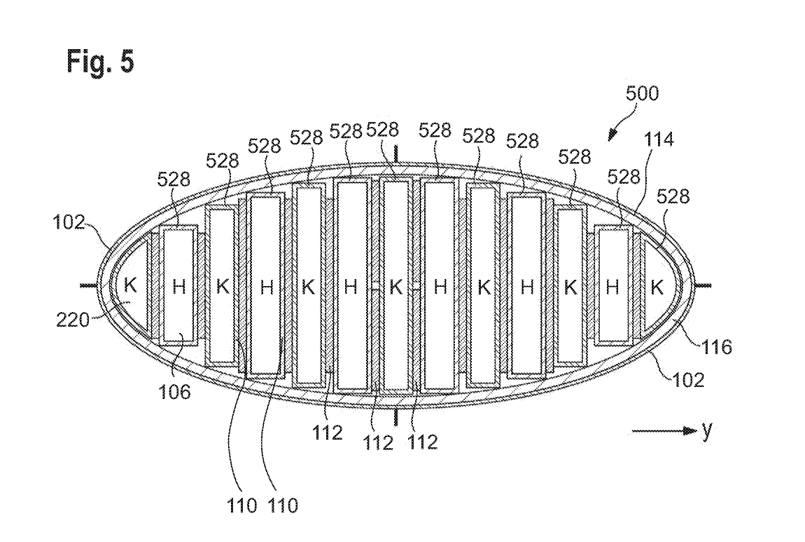

FIG. 5 finally shows a fifth embodiment of a thermoelectric generator unit 500.

An outer housing 102 is also provided here, an elastic compensating element 116 extending along the inside 114 thereof. As for the fourth embodiment, the outer housing 102 is configured to have an oval shape.

In contrast to the previous embodiments, in which the inner ducts 106, 220 extend parallel to the long axis of the oval cross-sectional area, the inner ducts 106, 220 are here oriented parallel to the short axis. A larger number of inner ducts 106, 220 is accordingly provided, first and second inner ducts 106, 220 respectively alternating. A second inner duct 220 carrying a cold fluid K is respectively arranged on the narrow sides of the outer housing 102. All inner ducts 106, 220 are here formed by individual tubes 528. One or several thermoelectric modules 112 is/are respectively placed between the individual tubes 528.

The assembly composed of the tubes 528 and the thermoelectric modules 112 is wrapped by the elastic compensating element 116 and is held together in the outer housing 102 by the elastic clamping force thereof.

The housing 102 can always be composed of two half shells, for example, which can be separated along the long axis or along the short axis. The outer housing 102 can of course also be wrapped in all variants. It is furthermore possible to use a closed tube as an outer housing 102, into which the represented parts such as the tube, the compensating elements and the modules are axially inserted and pressed as a pre-mounted overall unit. The tubes forming the inner ducts 106, 220 can be configured with a rectangular cross-section in all embodiments. All features of the individual embodiments can generally be combined with each other or exchanged for each other at the discretion of a person skilled in the art. However, at least 60% of the elastic compensating element 116 are always made of an organic material.

Although an embodiment of this invention has been disclosed, a worker of ordinary skill in this art would recognize that certain modifications would come within the scope of this disclosure. For that reason, the following claims should be studied to determine the true scope and content of this disclosure.

1. A thermoelectric generator unit comprising:
an outer housing in which at least one first inner duct is arranged through which a hot fluid flows;
at least one thermoelectric module which is in thermal contact with the first inner duct on a hot side; and
at least one elastic compensating element arranged within the outer housing and configured to generate a clamping force on the thermoelectric module, and wherein at least 60% of the elastic compensating element is made of an organic material.

2. The thermoelectric generator unit according to claim 1, wherein the organic material comprises an organic natural material.

3. The thermoelectric generator unit according to claim 1, wherein the organic natural material is selected from the group of fabrics consisting of: cork, flax, hemp, grass, bamboo fibers, bast, jute, sisal, kenaf, abacá fibers, coconut fibers, wool, seagrass, wood fibers, cotton, kapok or a mixture of or with these fabrics.

4. The thermoelectric generator unit according to claim 2, wherein the organic natural material is treated with a substance increasing the thermal stability thereof.

5. The thermoelectric generator unit according to claim 1, wherein the organic material comprises a polymer.

6. The thermoelectric generator unit according to claim 5, wherein the polymer is a high-temperature silicone, an elastomer, or a polyurethane.

7. The thermoelectric generator unit according to claim 1, wherein at least 80% of the elastic compensating element is made of the organic material.

8. The thermoelectric generator unit according to claim 1, wherein the organic material has a temperature resistance up to at least 180° C.

9. The thermoelectric generator unit according to claim 1, wherein the elastic compensating element is a mat having a uniform thickness.

10. The thermoelectric generator unit according to claim 1, wherein the elastic compensating element comprises a component-adapted shape having a varying thickness.

11. The thermoelectric generator unit according to claim 10, wherein the elastic compensating element comprises a cured foam which fills a space area within the outer housing.

12. The thermoelectric generator unit according to claim 1, wherein the elastic compensating element is placed on an inside of the outer housing.

13. The thermoelectric generator unit according to claim 1, wherein the outer housing has structures, and wherein the elastic compensating element rests on an inside of the outer housing in a region of the structures.

14. The thermoelectric generator unit according to claim 1, wherein at least a second inner duct through which a cold fluid flows is provided within the outer housing and wherein a cold side of the thermoelectric module is in thermal contact with the second inner duct.

15. The thermoelectric generator unit according to claim 1, wherein the thermoelectric module directly contacts a duct wall of the at least one first inner duct.

16. The thermoelectric generator unit according to claim 1, wherein the thermoelectric module projects into the inner duct and is in direct contact with the fluid flowing therethrough.

17. The thermoelectric generator unit according to claim 1, wherein the elastic compensating element is arranged between two inner ducts.

18. An exhaust system comprising:
a thermoelectric generator unit comprising an outer housing in which at least one first inner duct is arranged through which a hot fluid flows, at least one thermoelectric module which is in thermal contact with the first inner duct on a hot side, at least one elastic compensating element arranged within the outer housing and configured to generate a clamping force on the thermoelectric module, and wherein at least 60% of the elastic compensating element is made of an organic material; and
wherein the outer housing has an exhaust gas inlet and an exhaust gas outlet which are in fluid communication with the first inner duct.
